(19) United States
(12) Patent Application Publication
(10) Pub. No.: US 2025/0218745 A1
(43) Pub. Date: Jul. 3, 2025

(54) STATIC ELECTRCITY CONTROL DEVICE FOR SEMICONDUCTOR PROCESSING SYSTEM

(71) Applicant: NEXTIN, INC., Gyeonggi-do (KR)

(72) Inventor: Heung-Gyoon PARK, Gyeonggi-do (KR)

(21) Appl. No.: 18/867,257

(22) PCT Filed: Mar. 15, 2023
(86) PCT No.: PCT/KR2023/003460

§ 371 Date: Nov. 19, 2024

(30) Foreign Application Priority Data
May 20, 2022 (KR) 10-2022-0061887
May 30, 2022 (KR) 10-2022-0066175

(51) Int. Cl. H01J 37/32; H01J 37/08; H01J 37/09

(52) U.S. Cl. CPC H01J 37/32697; H01J 37/08; H01J 37/09; H01J 2237/0041; H01J 2237/0048; H01J 2237/0453

(57) ABSTRACT

Embodiments of the present invention relate to a technology for easily adjusting a level of static electricity required for a substrate according to a semiconductor process by injecting static electricity into the substrate or removing static electricity already formed on the substrate. A static electricity control device for injecting static electricity into a substrate disposed in a vacuum chamber or removing static electricity formed on the substrate in a semiconductor processing system, according to an embodiment, comprises: a charged particle generation unit, disposed on an upper side inside the vacuum chamber, that generates charged particles including positive ions and electrons by generating a vacuum ultraviolet ray (VUV) and reacting the VUV with a process gas inside the vacuum chamber; a grid provided with a plurality of holes, disposed on a lower side of the charged particle generation unit, that selectively pass the type of charged particles downward according to an input voltage; a substrate support, disposed below the grid and having the substrate positioned thereon, that is made of a conductive material and guides the charged particles passing through the grid toward the substrate at a predetermined density according to an input bias voltage; and a static electricity control unit that controls the static electricity of the substrate by supplying a pulsed voltage to at least one of the grid and the substrate support, wherein the grid and the substrate support are arranged so as to have a separation distance that is within four times the mean free path of the process gas according to environmental conditions of the vacuum chamber.

### TECHNICAL FIELD

The present disclosure generally relates to a technology for easily adjusting a level of static electricity required for a substrate according to a semiconductor process by injecting static electricity into the substrate or removing static electricity formed on the substrate.

### BACKGROUND ART

Recently, as the integration of semiconductor industries increases, the size and area of semiconductor devices are decreasing.

Accordingly, the size of a pattern forming a semiconductor device and the thickness of a thin film are decreasing, and in particular, factors that did not have a significant effect in the past are emerging as important factors in the development of semiconductor devices. Static electricity formed on a substrate is one of these factors, and therefore, a process for controlling static electricity formed on the substrate is being applied.

During a deposition, etching, or substrate cleaning process using plasma among semiconductor processes, static electricity is formed on a substrate. When a voltage of the static electricity is too high or discharging occurs suddenly after charging inside the substrate, pattern deformation or the like may occur due to phenomena such as arcing and the like.

Further, static electricity formed on a substrate is mainly generated by electric charges generated when a process of using of deionized water, transferring electric charge from charged plastic materials, or using induction charging or plasma is performed.

In order to prevent the generation of the static electricity, a device is used for the purpose of controlling, before a pattern formation process, a cleaning process, or a plasma treatment process, fine patterns such as for local pattern uniformity and local edge arrangement errors during a multi-patterning process and controlling (trade-off) static electricity generated during other processes by pre-charging (injecting) positive charges (ions) or negative charges (electrons) into an insulator (thin film) of the substrate within several nanometers to several tens of nanometers. This is called a static electricity charger.

Meanwhile, the static electricity of the substrate is mainly generated during a photolithography process or a cleaning process that utilizes rotational motion, and it is known that the most static electricity is concentrated in a central part of the substrate due to a difference in centrifugal force. That is, in the photo resist coating process, the concentration of air flow in the central part of the substrate is three times greater than that in a periphery of the substrate due to the high-speed rotation of a wafer, and thus the static electricity is formed around the central part of the substrate where centrifugal force is a relatively low. The static electricity generated with a strong electric field formed at the central part of the substrate is charged to an inside of a multilayer insulating film, a surface of the wafer, or a photoresist pattern formed on the surface.

Accordingly, a method of efficiently removing static electricity formed on a substrate is required, and a device that removes the static electricity already generated on the substrate or the static electricity generated during a process is called a static electricity discharger.

FIG. 1A illustrates an example of a shape in which static electricity voltages of −50 V, −30 V, and −10 V are applied from a central part of a substrate 1 to an outer side of the substrate.

However, when the central part of the substrate 1 is charged with a high voltage as illustrated in FIG. 1A, not only is a surface of the substrate 1 such as a photo resist (P/R) or oxide, which is an insulator, are charged with electric charges, but up to a certain depth D of the surface of the substrate is also charged, in an area (the area in which the static electricity voltage is-50 V) corresponding to the central part of the substrate in FIG. 1B, and thus a state in which neutralization by ions with low kinetic energy is impossible may occur.

Further, the static electricity voltage with which the substrate is charged has depended on many variables such as the types of processes, materials, pattern shapes, etc., and is generally formed between-100 V and +100 V.

For example, as illustrated in FIG. 1B, a charging voltage of 100 V or less is formed on the substrate 1 on which an insulating film within a microcircuit of 10 nm or a pattern P having an aspect ratio of “5” or more is formed, but since a width of the pattern is narrow, it is difficult to remove the static electricity accumulated inside a thin film due to a decrease in ion collisions caused by a self-neutralizing effect between positive and negative ions generated from an ionizer and a low electromotive force due to a low voltage difference between the substrate and the ions.

### DISCLOSURE

### Technical Problem

Conventionally, static electricity was removed from a substrate using an ionizer. As shown in FIG. 2, in a method of using an ionizer, however, when a substrate is charged with static electricity of 1000 V, reducing static electricity within 100 V or less using a soft X-ray ionizer has a decay time of 1 to 2 seconds, and when an initial charging voltage is 100 V or less, it takes a long time to reduce the charging voltage to a level lower than the charging voltage.

Further, considering that the ion density by an ionizer is generally 10⁶ cm², when charging occurs inside a silicon oxide layer under a PR in a substrate and the ion density becomes 10⁸ cm² or higher, static electricity formed inside a substrate 1 cannot be removed using a conventional ionizer.

One of objects to be solved by this technology is to resolve the difficulties of the above-described conventional technology. The present invention is directed to providing a static electricity control device in a semiconductor processing system that is capable of accurately and rapidly injecting static electricity into a substrate or easily removing the static electricity formed on the substrate using a simple method of controlling voltages applied to a grid and a substrate support.

### Technical Solution

One aspect of the present invention provides a static electricity control device in a semiconductor processing system, for injecting static electricity into a substrate disposed in a vacuum chamber or removing static electricity formed on the substrate. The static electricity control device includes a charged particle generation unit that is disposed on an upper inner side of the vacuum chamber and generates charged particles including positive ions and electrons by generating a vacuum ultraviolet (VUV) ray and reacting the VUV ray with a process gas inside the vacuum chamber, a grid disposed below the charged particle generation unit and including a plurality of holes that allow the charged particles to selectively pass downward according to an input voltage, a substrate support that is disposed below the grid, has an upper surface on which the substrate is positioned, and guides the charged particles passing through the grid toward the substrate at a predetermined density according to an input bias voltage, and a static electricity control unit configured to control the static electricity of the substrate by supplying a pulsed voltage to at least one of the grid and the substrate support, wherein the grid and the substrate support are arranged to have a separation distance that is within four times a mean free path of the process gas according to environmental conditions of the vacuum chamber.

In one aspect of the present embodiment, in a static electricity injection mode, the static electricity control unit may apply the bias voltage applied to the substrate support to be higher than a voltage applied to the grid by a certain level or more and in a static electricity removal mode, may apply the voltage applied to the grid and the bias voltage applied to the substrate support to be within a predetermined similar range.

In one aspect of the present embodiment, the static electricity control unit may control a voltage level by controlling a cycle of pulses applied to the grid and the substrate support.

In one aspect of the present embodiment, the charged particle generation unit may include at least one VUV lamp that emits a VUV ray.

In one aspect of the present embodiment, a beam generator that emits a line-shaped ion beam through a side surface of the vacuum chamber may be additionally provided at a lower side of the VUV lamp, and the charged particles by the reaction between the VUV ray and the process gas and charged particles by a reaction between the ion beam and the process gas may be simultaneously generated to increase the density of the charged particles.

In one aspect of the present embodiment, the charged particle generation unit may include a plasma generator that generates plasma, and separation plates that are disposed below the plasma generator and allow only a VUV ray to pass therethrough, and the charged particle generation unit may generate charged particles by a reaction between the VUV ray generated by the plasma generator and the process gas.

In one aspect of the present embodiment, the plasma generator may include one or more micro plasma devices that generate plasma using power in a range of 10 to 200 W in a vacuum environment in which a volume of the vacuum chamber ranges from 500 to 1000 cc.

In one aspect of the present embodiment, the static electricity control unit may control the static electricity of the substrate by adjusting at least one of a type of the process gas injected into a vacuum chamber of the micro plasma device and plasma power.

In one aspect of the present embodiment, the plasma generator may include a plurality of micro plasma devices, and the static electricity control unit may control the static electricity of the substrate by individually adjusting the type of process gas injected into the vacuum chamber of each micro plasma device or plasma power.

In one aspect of the present embodiment, the plasma generator may include a plurality of micro plasma devices, the separation plates may be disposed in a one-to-one correspondence with the respective micro plasma devices, the static electricity control unit may control the static electricity of the substrate by individually adjusting the type of process gas injected into the vacuum chamber of each micro plasma device or plasma power, and lenses having different divergence angles may be provided on each of the separation plates.

In one aspect of the present embodiment, the grid and the substrate support may be a multi-zone type in which a plurality of areas are electrically separated, and the static electricity control unit may individually supply different levels of voltages to the areas of each of the grid and substrate support.

In one aspect of the present embodiment, the static electricity control unit may supply the voltages to the areas of each of the grid and substrate support so as to inject the static electricity into a certain part of the substrate and remove the static electricity from another part of the substrate.

In one aspect of the present embodiment, the grid may include an upper grid and a lower grid disposed below the upper grid, and the static electricity control unit may supply different levels of voltages to the upper grid and the lower grid.

In one aspect of the present embodiment, a diameter of a hole formed in the lower grid may be set to be different from a diameter of a hole formed in the upper grid, and the static electricity control unit may control electrons with a higher density to be emitted toward the substrate through the hole of the lower grid by secondary electrons, which are generated by the ions introduced through the lower grid to collide with a lower surface of the upper grid, by applying a negative voltage of a first level to the lower grid to guide ions between the lower grid and the substrate toward the upper grid through the holes of the lower grid and then applying a negative voltage of a level greater than the first level to the upper grid.

In one aspect of the present embodiment, a hole aperture ratio of a central part of the grid may be higher than a hole aperture ratio of a peripheral area of the grid.

In one aspect of the present embodiment, the static electricity control device may further include a distance adjustment unit configured to move the grid and the substrate support up and down inside the vacuum chamber, wherein the static electricity control unit may control the distance adjustment unit so that a position of at least one of the grid and the substrate support is changed upward or downward on the basis of the mean free path of the process gas calculated according to the environmental conditions of the vacuum chamber.

In one aspect of the present embodiment, a surface of the grid may be coated with a film containing carbon components including carbon, a carbon nanotube (CNT), and glassy carbon or may be sputtered therewith to prevent the occurrence of an arc.

In one aspect of the present embodiment, a surface of the grid may be coated with one of silicon oxide (SiO₂), aluminum oxide (Al₂O₃), silicon nitride (Si₃N₄), and an oxide-based thin film or may be sputtered therewith to prevent the occurrence of an arc.

### Advantageous Effects

According to the present technology, it is possible to accurately and rapidly inject static electricity into a substrate or easily remove the static electricity formed on the substrate. Therefore, it is possible to minimize a defect rate due to a semiconductor manufacturing process and manufacture more reliable semiconductor devices.

### DESCRIPTION OF DRAWINGS

FIG. 1 is a set of diagrams for describing a problem of removing static electricity from a semiconductor.

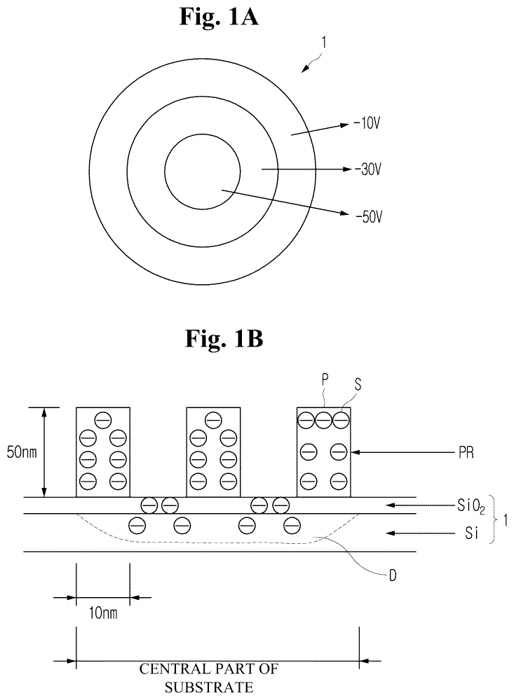

FIG. 2 is a diagram for describing the static electricity removal characteristics of a natural diffusion method using an ionizer.

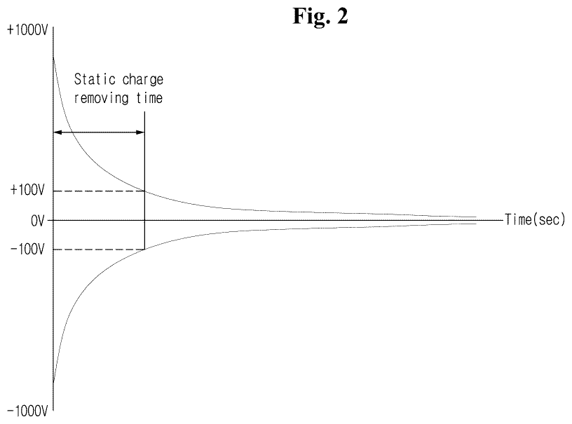

FIG. 3 is a schematic diagram illustrating a semiconductor processing system equipped with a static electricity control device according to a first embodiment.

FIG. 4 is a set of diagrams illustrating a configuration of a charged particle generation unit illustrated in FIG. 3.

FIG. 5 is a diagram for describing a multi-zone structure of a grid and a substrate support illustrated in FIG. 3.

FIG. 6 is a set of diagrams for describing a dual grid structure of the grid illustrated in FIG. 3.

FIG. 7 is a set of diagrams showing results of static electricity injection and static electricity removal experiments according to a distance between the grid and the substrate support illustrated in FIG. 3.

FIG. 8 is a flowchart for describing an operation of the static electricity control device in the semiconductor processing system illustrated in FIG. 3.

### BEST MODE OF THE INVENTION

Since configurations illustrated in embodiments described in this specification and the accompanying drawings are only exemplary embodiments and do not represent the overall technological scope of the present invention, it is understood that the present invention covers various equivalents, modifications, and substitutions at the time of filing of this application. The scope of the present invention should not be construed as being limited by the embodiments described in this specification and the accompanying drawings. That is, since the embodiments can be modified in various ways and can take various forms, the scope of the present invention should be understood to include equivalents that can realize the technical idea. Further, the purpose or effects presented in the present invention do not mean that a specific embodiment should include all of them or only include such effects, and therefore, the scope of the present invention should not be understood as being limited thereby.

Unless otherwise defined, all terms used herein have the same meaning as commonly understood by one of ordinary skill in the art to which this invention belongs. It should be further understood that terms, such as those defined in commonly used dictionaries, should be interpreted as having a meaning that is consistent with their meaning in the context of the relevant art and are not to be interpreted in an idealized or overly formal sense unless expressly so defined herein.

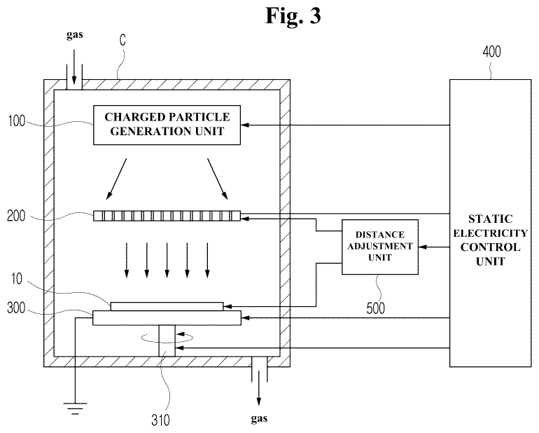

FIG. 3 is a schematic diagram illustrating a semiconductor processing system equipped with a static electricity control device according to a first embodiment of the present invention.

Referring to FIG. 3, the semiconductor processing system according to the present invention may include a charged particle generation unit 100 that is disposed on an upper inner side of a vacuum chamber C in which a substrate 10 is disposed, a grid 200 and a substrate support 300 that are sequentially arranged below the charged particle generation unit 100, and a static electricity control unit 400 that controls the injection of static electricity into the substrate 10 or the removal of static electricity formed on the substrate 10 by generating charged particles in the vacuum chamber C through the charged particle generation unit 100 and controlling a voltage to be applied to the grid 200 and the substrate support 300 to adjust the density of the charged particles emitted toward the substrate 10 through the grid 200.

Further, the semiconductor processing system may further include a distance adjustment unit 500 that adjusts a distance between the grid 200 and the substrate support 300 by adjusting a position of at least one of the grid 200 and the substrate support 300 upward or downward under the control of the static electricity control unit 400.

That is, in the present embodiment, the charged particles that are generated in the vacuum chamber C are selectively transmitted through the grid 200, and a bias voltage is applied to the substrate support 300 that supports the substrate 10 and guides the charged particles passing through the grid 200 toward the substrate 10 to inject the static electricity into the substrate 10 or neutralize (remove) the static electricity formed on the substrate 10.

Next, the present embodiment will be described in more detail.

The vacuum chamber C is equipment in which a semiconductor process is performed on the substrate 10, and although not illustrated, includes a vacuum forming unit for maintaining the inside of the chamber in a vacuum state and a gas supply unit for supplying gas into the inside of the chamber.

In this case, the vacuum forming unit may include a vacuum pump that discharges a material inside the chamber to the outside of the chamber, a vacuum gauge that can detect an internal vacuum level, a valve that controls the introducing and discharging of the material, and a pipe that connects the respective components. In addition, the vacuum forming unit preferably maintains the vacuum level inside the chamber at 10-1 to 10-4 Torr.

The gas supply unit may supply different gases depending on the process and provide gases such as helium (He), nitrogen (N₂), argon (Ar), and the like into the chamber, and a flow rate of the gases may be set to 10 to 1,000 sccm.

The charged particle generation unit 100 is a device that generates a vacuum ultraviolet (VUV) ray and reacts the VUV ray with a process gas to generate charged particles including positive ions and electrons. The charged particle generation unit 100 includes at least one of a VUV lamp and a plasma generator, and may additionally generate a line-shaped ion beam, a large-area electron beam etc., using plasma to generate charged particles including electrons and ions.

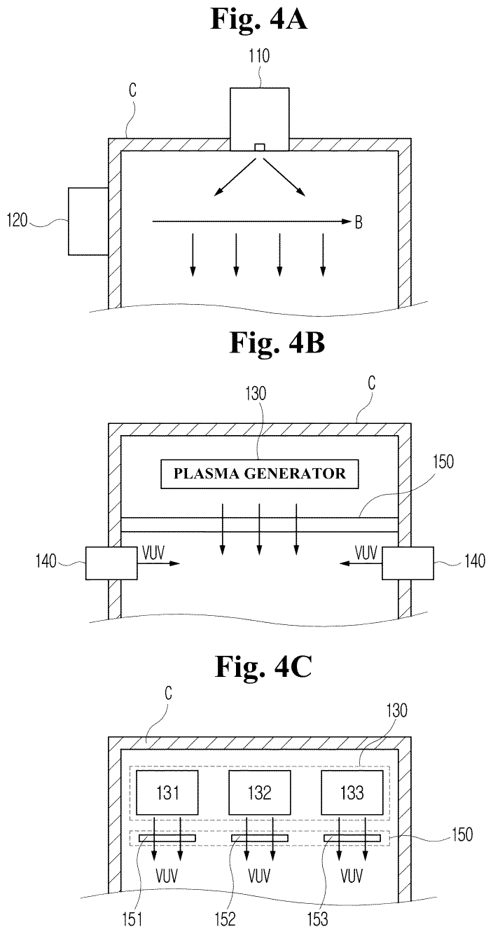

FIG. 4 illustrates a configuration of the charged particle generation unit 100.

As illustrated in FIG. 4A, the charged particle generation unit 100 may further include a VUV lamp 110 positioned on an upper side of the vacuum chamber C, and a beam generator 120 that is positioned below the VUV lamp 110 and emits a large-area beam B, that is, an ion beam or an electron beam, into the vacuum chamber C from a side surface of the vacuum chamber C. In this case, the VUV lamp 110 may be provided as a plurality of VUV lamps 110. That is, the VUV lamps 110 generate a VUV ray with a wavelength range of 110 nm to 400 nm and irradiate the inside of the vacuum chamber C with the generated VUV ray. The VUV ray reacts with the process gas inside the vacuum chamber C to decompose gas particles and generate charged particles including positive ions and electrons.

The beam generator 120 may further increase the density of electrons and positive ions emitted toward the grid 200 by dissociating the process gas inside the vacuum chamber C through an ion beam or an electron beam and additionally generating positive ions and electrons. Here, the configuration of the beam generator 120 that generates a line-shaped beam is disclosed in Korean Patent Nos. 10-1911542, 10-1989847, 10-1998774, and 10-2118604, which are patents of the inventor of the present application, and their detailed descriptions are omitted because they are all included in the present application.

Further, in the charged particle generation unit 100, a plasma generator 130 is disposed inside the vacuum chamber C as illustrated in FIG. 4B. The plasma generator 130 may generate charged particles including positive ions and electrons by reacting the VUV ray formed in the plasma with the process gas.

A VUV lamp 140 that emits a VUV ray into the vacuum chamber C from the side surface of the vacuum chamber C may be additionally disposed on the lower side of the plasma generator 130. In this case, a plurality of VUV lamps 140 may be disposed, and may be positioned on each of both side surfaces of the vacuum chamber C as illustrated in FIG. 4B.

The electrons excited in the plasma formed by the plasma generator 130 transition to a ground state and light with energy corresponding to an energy difference between an excited state and the ground state is emitted to the outside. A wavelength band of the light formed in this way is an ultraviolet band which can dissociate the gas provided by the gas supply unit and generate particles with a negative electric charge and/or particles with a positive electric charge.

The plasma generator 130 may be an inductively coupled plasma (ICP) generating device or a capacitively coupled plasma (CCP) generating device. An electrical signal supplied to the plasma generator 130 may be a pulse or a continuous wave (CW). For example, the ultraviolet band may be classified by its wavelength range into a near ultraviolet (NEAR UV, 300 nm to 380 nm) ray band, a far ultraviolet (FAR UV, 200 nm to 300 nm) ray band, and a VUV ray (70 nm to 200 nm) band having a shorter wavelength than the far ultraviolet band, and the plasma generator 130 in the present invention may form ultraviolet rays in the VUV ray band.

The plasma generator 130 may be formed as micro plasma source that generates plasma using direct current (DC), radio frequency (RF), and pulsed power in a range of 10 to 200 W in an environment where the volume of the vacuum chamber is in a range of 500 to 1000 cc, the micro plasma source includes a separate vacuum chamber for forming plasma, and units for performing gas injection and gas exhaust processing into and from the vacuum chamber, vacuum processing, and power supply processing under the control of the static electricity control unit 400.

In this case, the micro plasma source is composed of one of atmospheric pressure plasma devices using ICP, CCP, transformer coupled plasma (TCP), a hollow cathode, and dielectric barrier discharge (DBD) plasma, and generates plasma using various process gases including oxygen, nitrogen, argon, and helium.

The micro plasma source has an advantage of being able to freely turn plasma on/off, easily changing process conditions, and having a short plasma turn-on time because the volume of the vacuum chamber is in a range of 500 to 1000 CC, compared to VUV lamps that typically require a preheating time of about 30 seconds and cannot control an output of a light source. When the micro plasma source is used, a process time required for a semiconductor multilayer thin film is longer than necessary, and thus it is possible to prevent the deterioration of thin film properties and to more rapidly and adaptively inject or remove static electricity into or from the substrate.

Further, in the present invention, as illustrated in FIG. 4C, the plasma generator 130 may be provided as a plurality of micro plasma sources. In FIG. 4C, first to third micro plasma sources 131, 132, and 133 are illustrated.

In the embodiment illustrated in FIG. 4C, each of the first to third micro plasma sources 131, 132, and 133 may be implemented in an independent vacuum chamber, and the static electricity control unit 400 may be configured to individually control the vacuum environment, the type of process gas, plasma power, etc., of each of the first to third micro plasma sources 131, 132, and 133 to perform different static electricity injection treatments or different static electricity removal treatments on different areas of the substrate 10.

That is, when more static electricity is formed in the central part of the substrate 10 than in a periphery of the substrate 10, the static electricity control unit 400 may set pressure or power of the micro plasma source corresponding to the corresponding position to be differently from the pressure or power of the micro plasma source at other positions. This enables a more precise static electricity control process to be performed compared to a VUV lamp that cannot control the wavelength of the VUV ray being output.

Further, a main wavelength of the VUV ray generated from the micro plasma source is 58.4 nm when helium gas is used as the process gas, 130.5 nm when oxygen gas is used as the process gas, and 104.8 nm when argon gas is used as the process gas, depending on the type of process gas. Accordingly, the static electricity control unit 400 may select a desired wavelength of the VUV ray by varying or mixing the types of process gases supplied to the vacuum chambers of the first to third micro plasma sources 131, 132, and 133, and accordingly, allow the level of the static electricity injected into or removed from the substrate 10 to be set differently for each area. For example, when the band gap energy of the semiconductor thin film formed on the substrate 10 is large, helium gas may be used, and when the band gap energy is small, nitrogen gas may be used.

Further, the static electricity control unit 400 may selectively operate only the micro plasma source at the position corresponding to the area of the substrate 10 requiring static electricity control.

In addition, depending on the usage environment including the type of the target substrate for static electricity control, the first to third micro plasma sources 131, 132, and 133 may be implemented as different types of atmospheric pressure plasma devices using ICP, CCP, TCP, a hollow cathode, and DBD plasma.

Meanwhile, in order to utilize the wavelength of the VUV ray formed in the plasma, as illustrated in FIG. 4B, a separation plate 150 made of MgF₂ glass or CaF₂ glass may be disposed on the lower side of the plasma generator 130 to block positive ions, electrons, active species generated by the plasma generator 130 from being emitted downward and to transmit only the VUV ray. In this case, the charged particles generated by a reaction between the VUV ray generated by the plasma generator 130 and the process gas and the charged particles generated by a reaction between the VUV ray emitted from the VUV lamp and the process gas are simultaneously generated.

The separation plate 150 may additionally include an optical filter coating unit that selectively transmits only the VUV ray to emit light of a size of 10 to 20 mm downward, and a divergence angle of the VUV ray emitted downward may be set to a desired angle using a concave lens or a convex lens. In the embodiment illustrated in FIG. 4C, when the separation plate 150 is implemented, the separation plate 150 may be provided as separation plates 151, 152, and 153 to be respectively disposed on lower sides of the first to third micro plasma sources 131, 132, and 133 and the separation plates 151, 152, and 153 may have different divergence angles. For example, a convex lens may be provided on the lower side of each of the first and third micro plasma sources 131 and 133, and a concave lens may be provided on the lower side of the second micro plasma source 132. Of course, as in the embodiment in FIG. 4B, it is also possible to provide a configuration in which lenses having different divergence angles are provided on one separation plate 150 to correspond to the respective micro plasma sources.

Further, an optical diffusion plate (not illustrated) may be disposed on a front surface of the VUV lamp 140 to diffuse the VUV ray into the vacuum chamber C.

Meanwhile, the grid 200 is provided in the form of a plate made of a conductive material, and a plurality of microscopic holes for discharging the charged particles introduced from the upper side to the lower side are formed. Considering that the substrate 10 is always formed to have a static electricity charging voltage higher at the central part than at the outer side after the process, an aperture ratio of the microscopic hole at the central part of the grid 200 is preferably 10% or more higher than that of a peripheral area of the grid 200, and the microscopic hole may have a shape such as a circle or a diamond, and a diameter thereof may be set to a range of 1 to 10 mm.

The grid 200 selectively discharges the charged particles toward the substrate 10 according to the voltage supplied through the static electricity control unit 400.

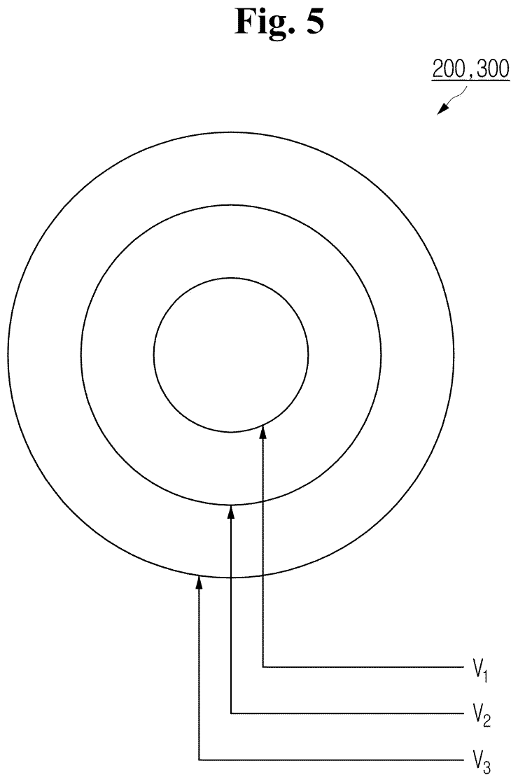

Further, the grid 200 may be configured as a multi-zone type in which a plurality of areas are electrically separated, as illustrated in FIG. 5, and may be configured so that different voltages V1, V2 and V3 are individually supplied to the respective areas. In this case, considering that the central part of the substrate 10 is formed to have a higher static electricity voltage than the outside is, the voltage supplied to the central part of the grid 200 may be set higher than that of a peripheral area of the grid 200 (V1>V2>V3) is. That is, a higher density of the charged particles may be supplied to the central part of the substrate 10.

In a multi-zone type of grid 200, a circular or square graphite or metal plate with a thickness of 5 mm to 10 mm, which is separated into multi-zones, is prepared, and a polyimide film of 50 μm to 100 μm and a copper (Cu) film of 20 to 100 μm are laminated onto the metal plate or graphite. Next, both sides of the copper (Cu) film are patterned and then etched so that a metal plate or graphite is patterned to be electrically isolated. In addition, a plurality of holes are formed to have a diameter of 1 to 10 mm, and insides of the holes are plated. In this case, the holes may have an aperture ratio of 50% or more of the metal plate or graphite surface, and the insides of the holes may be subjected to 20 μm electroless plating and 30 μm electrolytic plating.

Further, the grid 200 may be configured to prevent the occurrence of an arc by coating or sputtering a film containing a carbon component including carbon, a carbon nanotube (CNT), glassy carbon, etc., or one of DLC (diamond like carbon), silicon oxide (SiO₂), aluminum oxide (Al₂O₃), silicon nitride (Si₃N₄), oxide-based thin films, etc., to have a thickness of 100 to 1000 nm, on the surface thereof. From this, it is possible to prevent the occurrence of defects such as pattern distortion, pattern shrinkage, and line edge roughness (LER) of an ultra-fine pattern of several nanometers in size formed on the substrate 10 due to the arc occurring on the surface of the grid 200 due to a partial concentration phenomenon caused by a concentration phenomenon of ions and electrons on the upper side of the grid 200.

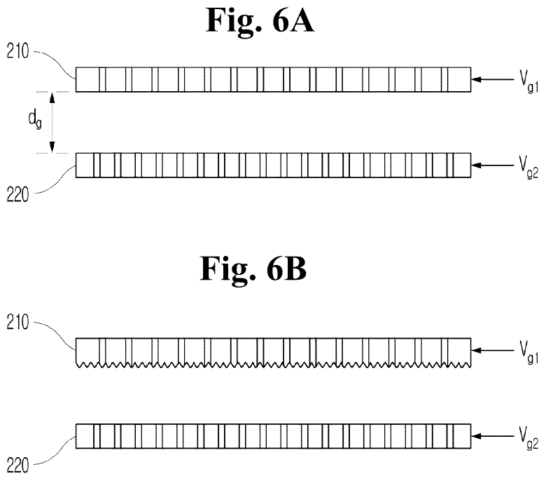

Further, the grid 200 may be formed as a dual grid structure consisting of an upper grid 210 and a lower grid 220, as illustrated in FIG. 6. In this case, different voltages Vg1 and Vg2 are each provided to the upper grid 210 and the lower grid 220 from the static electricity control unit 400. That is, a voltage of, for example, 50 to 100 V, which is sufficient to induce electric charges inside the vacuum chamber C into the hole of the grid, is provided to the upper grid 210 and a voltage of 300 to 500 V is provided to the lower grid 220 so that electric charges that have entered the hole of the grid has sufficient kinetic energy to be discharged to the substrate thereunder.

In the dual grid structure, since the electric charges between the charged particle generation unit 100 and the grid 200 is guided to the hole of the grid by the low voltage of the upper grid 210 when the electric charges collide with the surface of the grid 200, the occurrence of phenomena such as an arc and the like at the upper part of the grid may be prevented. Further, the electric charges are more widely distributed through the holes of the upper grid 210 and the lower grid 220 disposed to be spaced a certain distance dg from each other, and thus the uniformity of the electric charges emitted toward the substrate 10 may be increased.

Further, the grid 200 of the dual grid structure may be formed so that the diameter of the hole of the lower grid 220 is set to be 10 to 20% smaller than the diameter of the hole of the upper grid 210 to additionally generate secondary electrons within the grid 200, and thus the density of the electric charges emitted toward the substrate 10 may be further increased.

That is, the upper grid 210 serves as a cathode that emits secondary electrons and is composed of a material such as aluminum, anodized Al, carbon, a CNT, etc., and when a negative voltage of −50 to −150 V is applied to the lower grid 220, ions formed between the lower grid 220 and the substrate 10 are provided to the upper grid 210, and when a larger negative voltage, for example, a voltage of −200 to −1000 V, is applied to the upper grid 210, the ions may collide with the lower surface of the upper grid (cathode) to generate secondary electrons. Accordingly, electrons of about 10³ cm² formed between the lower grid 220 and the substrate 10 by the VUV ray and secondary electrons additionally generated inside the grid 200 are simultaneously emitted toward the substrate 10, and thus the density of the electrons applied toward the substrate 10 is increased to 10⁶ to 10⁸ cm², thereby increasing the process efficiency.

The lower surface of the upper grid 210 may be configured to have roughness as illustrated in FIG. 6B to form the direction of movement of the secondary electrons wider and improve the uniformity. Since the generation of secondary electrons through this dual grid structure does not generate active species (radicals) with chemical properties, a process that does not damage the substrate 10 is possible. In particular, since an electron beam can inject high density electrons into a specific area in a short period of time when the static electricity is injected, the physical impact on the substrate 10 may be minimized.

Meanwhile, the substrate support 300 is configured in a plate shape made of a dielectric material or a conductive material and provides kinetic energy so that the electric charges discharged from the grid 200 are directed toward the substrate 10 at a predetermined density according to a bias voltage supplied from the static electricity control unit 400.

In this case, the substrate support 300 may be divided into a plurality of areas so that different bias voltages are individually supplied to the plurality of areas from the static electricity control unit 400. For example, as illustrated in FIG. 5, when the areas of the grid 200 are divided and the voltage is individually supplied to each area, the substrate support 300 may be divided into the same areas as the grid 200 and bias voltages may be supplied to be the same polarity and the same voltage difference for each area of the grid 200. Further, only the grid 200 may be divided into a plurality of areas, the substrate support 200 may not be divided into a plurality of areas, and the grid 200 and the substrate support 200 may be divided to have areas of different shapes, and when static electricity control levels are different for each area, the voltages that are applied to the grid 200 and the substrate support 300 may have different voltage differences for each area. Accordingly, the static electricity injection process and the static electricity removal process may be performed simultaneously in different areas of the substrate 10.

Further, a rotating unit 310 for rotating the substrate support 300 may be additionally provided on the lower side of the substrate support 300, and the rotating unit 310 rotates the substrate support 300 at 1 to 30 RPM during the static electricity control process under the control of the static electricity control unit 400.

Further, in the present embodiment, the distance between the grid 200 and the substrate 10 is preferably set to within four times the mean free path of the process gas according to the environmental conditions of the inside of the vacuum chamber C.

In this case, a mean free path 2 of the process gas may be calculated through Equation 1 below.

$$λ = \frac{K \times T}{\sqrt{2} π \times {D}^{2} \times P} \qquad Equation 1$$

Here, K denotes a Boltzmann constant, T denotes a temperature, P denotes a pressure, and D denotes a diameter of a particle of the process gas.

The inventor of the present invention conducted a static electricity charging experiment using a 300 mm silicon wafer using a turbo vacuum pump in a chamber size of 330 mm (diameter)×150 mm (height) of a general semiconductor manufacturing device, and as a result of the experiment, it was found that, when the distance between the grid 200 and the substrate 10 is more than the mean free path (10 mm) and bias power is not supplied to the substrate support 300, the voltage of the substrate 10 after 30 seconds under the process conditions of 30 mTorr of pressure, 5 sccm, 100 mm of distance between the substrate and the grid, and +250 V of grid voltage when a 300 mm of silicon and SiO₂ 100 nm of deposition wafer are used, was +80 volts, which was a large difference from an expected voltage of −10 V.

In contrast, in the same process condition environment as above, the distance between the substrate 10 and the grid 200 was set to 10 mm, which is the mean free path according to the process gas and the pressure, and when a bias voltage of 200 V was supplied to the substrate 10, the voltage of the substrate 10 was guided to the target voltage −10 V. Through this, it was confirmed that the distance between the substrate 10 and the grid 200 and the bias voltage supplied to the substrate support 300 were important variables for controlling the static electricity on the substrate 10.

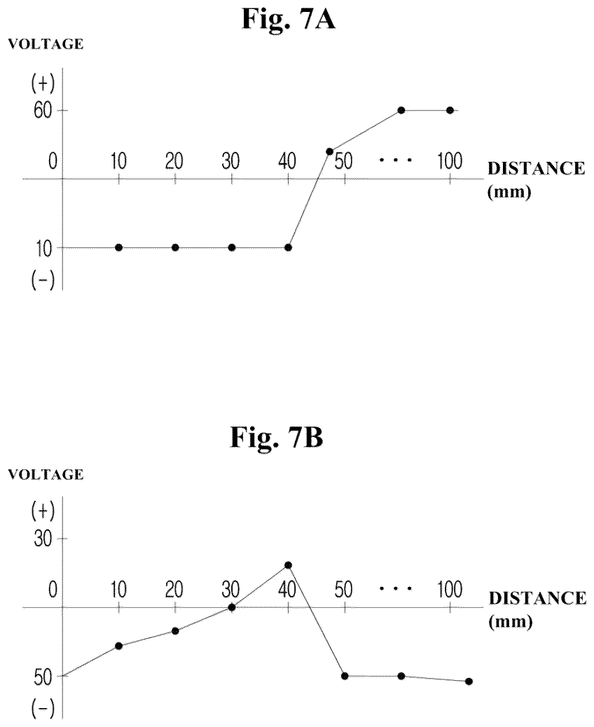

Further, as shown in FIG. 7, it was confirmed that the efficiency of static electricity injection or removal satisfied a certain range even when the distance between the grid 200 and the substrate 10 increased to 40 mm, which is four times the mean free path (10 mm) according to the process gas environment. FIG. 7A shows results measured using the QC 3000e system of Semilab, and as a result of the experiment on the static electricity injection process, it was confirmed that, under the process gas conditions described above, the same static electricity voltage was maintained on the substrate so that the distance between the grid 200 and the substrate 10 is up to 40 mm, which is four times the mean free path (10 mm) according to the process gas environment.

FIG. 7B shows results measured using the QC 3000e system from Semilab, and as a result of the experiment on the static electricity removal process, it can be seen that, under the process gas conditions described above, the static electricity is removed and the static electricity voltage converges to “0” when the distance between the grid 200 and the substrate 10 is up to 40 mm, which is four times the mean free path (10 mm) according to the process gas environment, but the static electricity is generated again at a distance greater than 40 mm.

It was confirmed that the efficiency of static electricity injection or removal according to the mean free path of electrons and positive ions is affected by the difference in the size of molecules compared to the process gas, selective electron or positive ions extraction at the top of the grid where ions and electrons are formed by the grid voltage, the bias field of the substrate support, and the rapid vacuum exhaust effect.

Meanwhile, the static electricity control unit 400 controls the voltage supplied to each device so that ions or electrons are supplied to the substrate 10 at a desired density, and controls the voltage so that the static electricity is injected into the substrate or the static electricity formed on the substrate 10 is removed. The static electricity control unit 400 controls the power level by adjusting the cycle of the pulse when power is supplied to the grid 200 and the substrate support 300.

In the static electricity injection mode, the static electricity control unit 400 supplies the voltage so that a difference in voltage between the grid 200 and the substrate support 300 is at least 2 times, for example, at least 2.5 times. That is, the bias voltage applied to the substrate support 300 is set at least 2.5 times higher than the voltage applied to the grid 200.

Further, in the static electricity removal mode, the static electricity control unit 400 supplies the voltage so that the difference in voltage between the grid 200 and the substrate support 300 is within a predetermined similar range, for example, the same.

Further, the static electricity control unit 400 supplies power such as DC, DC Pulse, or Reverse Pulse, AC, RF, etc., to the grid 200 and the substrate support 300, and when a voltage is supplied in the form of a pulse, the voltage is supplied so that the grid 200 and the substrate support 300 are in synchronized with each other, and thus the efficiency of static electricity injection or removal may be increased.

Further, since the density of ions and electrons can change depending on changes in gas flow rate, vacuum level, pumping speed, etc., in the vacuum chamber C, it is impossible to finely adjust the density with a direct current power source, and thus the static electricity control unit 400 may prevent over shooting from occurring on the substrate 10 by controlling the pulse on/off cycle or polarity of pulsed power applied to the grid 200 and the substrate support 300 to more accurately control the static electricity voltage.

That is, when the bias voltage is supplied to the substrate support 300, the charged particles that have passed through the grid 200 are accelerated toward the substrate 10 by electrical attraction, and the charged particles accelerated toward the substrate 10 allow the substrate 10 to be charged with the static electricity or neutralize the static electricity formed on the substrate 10.

When the static electricity is removed using electrons, the movement speed of the electrons is faster than that of positive ions, and thus a negative (−) overcharge phenomenon, that is, excessive static electricity, may occur on an insulating film on the surface of the substrate 10. Therefore, the static electricity control unit 400 may supply the bias voltage to the substrate support 300 by increasing or decreasing the bias voltage in a stepwise manner.

Further, when the static electricity is injected, the voltage supplied to the grid 200 or the substrate support 300 is adjusted to a voltage level at a certain time unit (several seconds) or the supply of the voltage stops to set an automatic neutralization time at a certain interval, and thus the static electricity control unit 400 may prevent overcharge on the surface without affecting the nano-sized ultra-fine pattern formed on the surface of the substrate 10.

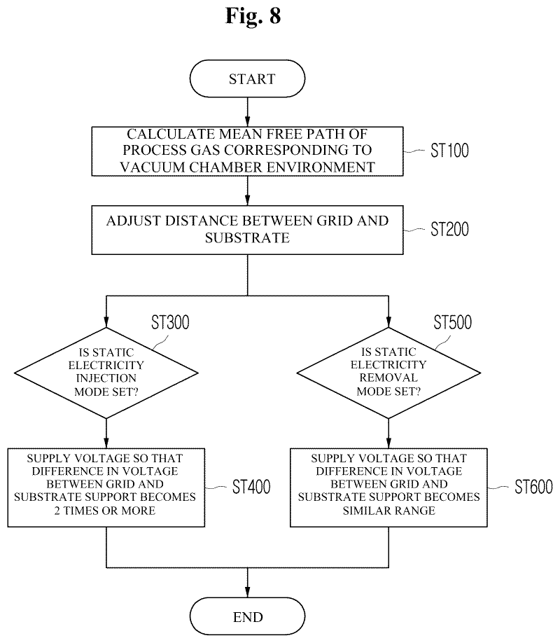

Next, an operation of the static electricity control device in the semiconductor processing system having the above-described configuration will be described with reference to FIG. 8.

First, the substrate 10 on which an insulating film is formed is disposed on the upper surface of the substrate support 300 provided in the vacuum chamber C. In this case, the insulating film formed on a surface of the substrate 10 is made of a material such as SiO₂, Si₃N₄, poly-Si, or doped oxide using plasma or an atomic layer deposition method, and a thickness of the insulating film may vary from 10 nm to 200 nm.

Next, the static electricity control unit 400 calculates a mean free path of a process gas corresponding to the vacuum chamber environmental conditions using Equation 1 above (ST100). In this case, various types of information including a temperature, a pressure, and a size of a molecule of a process gas for calculating the mean free path of the process gas may be pre-input by an administrator.

In addition, the static electricity control unit 400 controls the distance adjustment unit 500 to adjust the position of at least one of the grid 200 and the substrate support 300 upward or downward so that a distance between the grid 200 and the substrate 10 becomes within four times the mean free path of the process gas calculated in operation ST100 (ST200).

In the above-described state, the static electricity control unit 400 supplies the process gas to an inside of the vacuum chamber C under the predetermined environmental conditions to set a vacuum environment.

Further, the static electricity control unit 400 generates a VUV ray through the charged particle generation unit 100 and generates charged particles such as positive ions and electrons through a reaction between the VUV ray and the process gas. Typically, the density of ions by the VUV ray varies greatly depending on the pressure, but is approximately 10³ to 10⁴/cm², whereas the capacity of static electricity required in the substrate 10 is approximately 10⁸ to 10⁹ cm², requiring a lot of process time for static electricity injection. By additionally using a line beam-shaped ion beam using plasma, the density of ions may be formed at a high level of 10⁶ to 10⁷ cm², and thus the process time may be reduced. As illustrated in FIG. 4A, when the line-shaped beam is emitted from the side surface of the vacuum chamber C, no radicals having chemical properties are generated within the vacuum chamber C so that it is possible to perform a static electricity injection process without damaging the substrate 10, and as the process time is shortened, the time for VUV ray to come into contact with the insulating film is minimized so that changes in the insulating properties of the insulating film and the like may be reduced and productivity may be improved.

In the above-described state, when a static electricity injection mode is set by the administrator (ST300), the static electricity control unit 400 applies a predetermined voltage to the grid 200 and the substrate support 300, but supplies a bias voltage applied to the substrate support 300 to be at least twice as high as the voltage applied to the grid 200 (ST400). In this case, the voltage applied to the grid 200 is set higher than the voltage applied to the grid 200 in a static electricity removal mode, and a pulsed voltage may be supplied to at least one of the grid 200 and the substrate support 300.

Further, in operation ST300, the administrator sets a static electricity voltage to be injected into the substrate 10, and the static electricity control unit 400 calls voltage information to be supplied to the prestored grid 200 and the substrate support 300 that are pre-stored to correspond to the static electricity voltage requested by the administrator, and accordingly, supplies corresponding power to the grid 200 and the substrate support 300.

That is, in the state in which the distance between the grid 200 and the substrate support 300 is within four times the mean free path of the process gas, the charged particles generated in the charged particle generation unit 100 selectively pass through the microscopic hole by the voltage of the grid 200 and move toward the substrate 10, and the corresponding charged particles are emitted at a higher density toward the substrate 10 by the high voltage applied to the substrate support 300.

Meanwhile, in the state in which the distance between the grid 200 and the substrate support 300 is adjusted to within four times the mean free path of the process gas (ST200), when the static electricity removal mode is set by the administrator (ST500), the static electricity control unit 400 applies a predetermined voltage to the grid 200 and the substrate support 300, and sets the voltage applied to the grid 200 and the bias voltage applied to the substrate support 300 to be within the same or similar range (ST600). Here, a pulsed voltage may be supplied to at least one of the grid 200 and the substrate support 300.

In this case, in operation ST500, the administrator sets a removal static electricity voltage of the substrate 10, and the static electricity control unit 400 calls information on the voltage to be supplied to the prestored grid 200 and the substrate support 300 that are pre-stored to correspond to the static electricity removal voltage requested by the administrator, and accordingly, supplies corresponding power to the grid 200 and the substrate support 300.

That is, the removal of static electricity formed on the surface of the substrate is the same as in the static electricity injection process, but the static electricity embedded inside the multilayer film of the substrate 10 is neutralized by a VUV ray of 100 nm to 200 nm having energy greater than a band gap of each insulating film passing through the multilayer film to separate the static electricity into pairs of holes and electrons, while the static electricity formed on the upper part of the substrate 10 is neutralized using electrons and ions formed by the VUV ray, electron beams, and ion beams. For example, VUV ray energy at a wavelength band of 120 nm is 10.33 eV, band gap energy of silicon is 1.1 eV, and band gap energy of SiO₂ ranges from 9 to 10 eV.

Meanwhile, in the present invention, when the grid 200 and the substrate support 300 are formed in a multi-zone structure, the static electricity control unit 400 may control the injection of static electricity into a certain part of the substrate 10 and the removal of static electricity from another part of the substrate 10 by supplying different voltages corresponding to the injection and removal of static electricity to the respective areas of the grid 200 and the substrate support 300.

1. A static electricity control device for injecting static electricity into a substrate disposed in a vacuum chamber or removing static electricity formed on the substrate in a semiconductor processing system, comprising:
a charged particle generation unit that is disposed on an upper inner side of the vacuum chamber and generates charged particles including positive ions and electrons by generating a vacuum ultraviolet (VUV) ray and reacting the VUV ray with a process gas inside the vacuum chamber;
a grid disposed below the charged particle generation unit and including a plurality of holes that allow the charged particles to selectively pass downward according to an input voltage;
a substrate support that is disposed below the grid, has an upper surface on which the substrate is positioned, and guides the charged particles passing through the grid toward the substrate at a predetermined density according to an input bias voltage; and
a static electricity control unit configured to control the static electricity of the substrate by supplying a pulsed voltage to at least one of the grid and the substrate support,
wherein the grid and the substrate support are arranged to have a separation distance that is within four times a mean free path of the process gas according to environmental conditions of the vacuum chamber.

2. The static electricity control device of claim 1, wherein, in a static electricity injection mode, the static electricity control unit applies a bias voltage applied to the substrate support to be higher than a voltage applied to the grid by a certain level or more and in a static electricity removal mode, applies the voltage applied to the grid and the bias voltage applied to the substrate support to be within a predetermined similar range.

3. The static electricity control device of claim 2, wherein the static electricity control unit controls a voltage level by controlling a cycle of pulses applied to the grid and the substrate support.

4. The static electricity control device of claim 1, wherein the charged particle generation unit includes at least one VUV lamp that emits a VUV ray.

5. The static electricity control device of claim 4, wherein a beam generator that emits a line-shaped ion beam through a side surface of the vacuum chamber is additionally provided at a lower side of the VUV lamp, and the charged particles by the reaction between the VUV ray and the process gas and charged particles by a reaction between the ion beam and the process gas are simultaneously generated to increase the density of the charged particles.

6. The static electricity control device of claim 1, wherein the charged particle generation unit includes a plasma generator that generates plasma, and separation plates that are disposed below the plasma generator and allow only a VUV ray to pass therethrough, and the charged particle generation unit generates charged particles by a reaction between the VUV ray generated by the plasma generator and the process gas.

7. The static electricity control device of claim 6, wherein the plasma generator includes one or more micro plasma devices that generate plasma using power in a range of 10 to 200 W in a vacuum environment in which a volume of the vacuum chamber ranges from 500 to 1000 cc.

8. The static electricity control device of claim 7, wherein the static electricity control unit controls the static electricity of the substrate by adjusting at least one of a type of the process gas injected into a vacuum chamber of the micro plasma device and plasma power.

9. The static electricity control device of claim 7, wherein the plasma generator includes a plurality of micro plasma devices, and
the static electricity control unit controls the static electricity of the substrate by individually adjusting the type of process gas injected into the vacuum chamber of each micro plasma device or plasma power.

10. The static electricity control device of claim 7, wherein the plasma generator includes a plurality of micro plasma devices,
the separation plates are disposed in a one-to-one correspondence with the respective micro plasma devices,
the static electricity control unit controls the static electricity of the substrate by individually adjusting the type of process gas injected into the vacuum chamber of each micro plasma device or plasma power, and
lenses having different divergence angles are additionally provided on each of the separation plates.

11. The static electricity control device of claim 1, wherein the grid and the substrate support are arranged in a multi-zone type in which a plurality of areas are electrically separated, and the static electricity control unit individually supplies different levels of voltages to the areas of each of the grid and substrate support.

12. The static electricity control device of claim 11, wherein the static electricity control unit supplies the voltages to the areas of each of the grid and substrate support so as to inject the static electricity into a certain part of the substrate and remove the static electricity from another part of the substrate.

13. The static electricity control device of claim 1, wherein the grid includes an upper grid and a lower grid disposed below the upper grid, and
the static electricity control unit supplies different levels of voltages to the upper grid and the lower grid.

14. The static electricity control device of claim 13, wherein a diameter of a hole formed in the lower grid is set to be different from a diameter of a hole formed in the upper grid, and
the static electricity control unit controls electrons with a higher density to be emitted toward the substrate through the hole of the lower grid by secondary electrons, which are generated by the ions introduced through the lower grid to collide with a lower surface of the upper grid, by applying a negative voltage of a first level to the lower grid to guide ions between the lower grid and the substrate toward the upper grid through the holes of the lower grid and then applying a negative voltage of a level greater than the first level to the upper grid.

15. The static electricity control device of any one claim of claim 1, wherein a hole aperture ratio of a central part of the grid is higher than a hole aperture ratio of a peripheral area of the grid.

16. The static electricity control device of claim 1, further comprising a distance adjustment unit configured to move the grid and the substrate support up and down inside the vacuum chamber,
wherein the static electricity control unit controls the distance adjustment unit so that a position of at least one of the grid and the substrate support is changed upward or downward on the basis of the mean free path of the process gas calculated according to the environmental conditions of the vacuum chamber.

17. The static electricity control device of claim 1, wherein a surface of the grid is coated with a film containing carbon components including carbon, a carbon nanotube (CNT), and glassy carbon or is sputtered therewith to prevent the occurrence of an arc.

18. The static electricity control device of claim 1, wherein a surface of the grid is coated with one of silicon oxide (SiO₂), aluminum oxide (Al₂O₃), silicon nitride (Si₃N₄), and an oxide-based thin film or is sputtered therewith to prevent the occurrence of an arc.
